(19) United States
(12) Patent Application Publication
(10) Pub. No.: US 2020/0343285 A1
(43) Pub. Date: Oct. 29, 2020

(54) PACKAGING STRUCTURE FOR IMAGE SENSOR, LENS MODULE, AND ELECTRONIC DEVICE USING THE SAME

(71) Applicant: HON HAI PRECISION INDUSTRY CO., LTD., New Taipei (TW)

(72) Inventors: CHING-YU NI, New Taipei (TW); HSIANG-HUA LU, New Taipei (TW); TE-EN TSENG, New Taipei (TW)

(21) Appl. No.: 16/826,419

(22) Filed: Mar. 23, 2020

(30) Foreign Application Priority Data
Apr. 23, 2019 (CN) 201910328502.X

(51) Int. Cl. H01L 27/146

(52) U.S. Cl. CPC H01L 27/14618; H01L 27/14636; H01L 27/14627

(57) ABSTRACT

A packaging structure for an image sensor includes a circuit board, an image sensor, a first installation bracket, and a second installation bracket. The image sensor is fixed on the circuit board via a first adhesive layer with high viscosity. The first installation bracket is fixed on the image sensor via a second adhesive layer with less (lower) viscosity. The second installation bracket is sleeved on an outside of the first installation bracket and is fixed on the circuit board via a third adhesive layer with a low (the lowest) viscosity. In assembly, relative positionings of the image sensor, the first installation bracket, and the second installation bracket in that order can be performed and adjusted without disturbing earlier positionings, thus any misalignment of the image sensor can be avoided or reduced, and the quality of the packaging structure is improved.

### FIELD

The subject matter relates to image capturing.

### BACKGROUND

A packaging structure for image sensor includes an image sensor, a light source, a mirror, and other modules. In a process of packaging the image sensor, a large misalignment can occur between the image sensor and the packaging structure, which lowers the quality of the packaging structure and does not serve the needs of users.

### BRIEF DESCRIPTION OF THE DRAWINGS

Implementations of the present technology will now be described, by way of embodiments, with reference to the attached figures.

FIG. 1 is a diagrammatic view of an embodiment of a lens module.

FIG. 2 is a block diagram of an embodiment of an electronic device including the lens module of FIG. 1.

### DETAILED DESCRIPTION

It will be appreciated that for simplicity and clarity of illustration, where appropriate, reference numerals have been repeated among the different figures to indicate corresponding or analogous components. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

The term “comprising,” when utilized, means “including, but not necessarily limited to”; it specifically indicates open-ended inclusion or membership in the so-described combination, group, series, and the like.

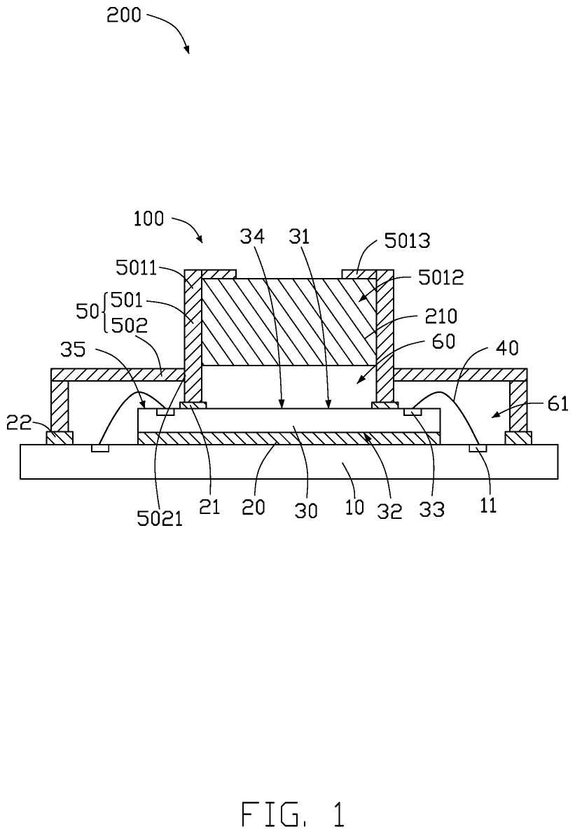

FIG. 1 illustrates a lens module in one embodiment (lens module 200). The lens module 200 includes a packaging structure 100 and a lens 210. The packaging structure 100 includes a circuit board 10, an image sensor 30, and an installation bracket assembly 50, and is configured for packaging the image sensor.

The circuit board 10 can be a printed or rigid circuit board or a flexible circuit board. In an alternative embodiment, the circuit board 10 is a printed circuit board. The circuit board 10 includes at least one first solder joint 11 on a surface thereof. The first solder joint 11 is electrically connected to electronic components on the circuit board 10. The electronic components can be all or some of a resistor, a capacitor, a diode, a transistor, a relay, or an electrically erasable programmable read only memory (EEPROM).

The packaging structure 100 further includes a first adhesive layer 20, a second adhesive layer 21, and a third adhesive layer 22. Viscosities of the first adhesive layer 20, the second adhesive layer 21, and the third adhesive layer 22 decrease in the order written. The first adhesive layer 20, the second adhesive layer 21, and the third adhesive layer 22 are made of polymer material such as epoxy resin.

The image sensor 30 includes a photosensitive surface 31 and a non-photosensitive surface 32 opposite to the photosensitive surface 31. The photosensitive surface 31 is positioned away from the circuit board 10, and the non-photosensitive surface 32 is adjacent to the circuit board 10. The non-photosensitive surface 32 is fixed on the circuit board 10 via the first adhesive layer 20. Since the viscosity of the first adhesive layer 20 is high, the position of the image sensor 30 in relation to the circuit board 10 will not change after the image sensor 30 is fixed on the circuit board 10 via the first adhesive layer 20. Therefore, the first adhesive layer 20 eliminates any difference in alignment between the image sensor 30 and the circuit board 10. An area of the image sensor 30 is less than an area of the circuit board 10. The image sensor 30 includes at least one solder joint 33, the number of the second solder joints 33 is the same as the number of first solder joints 11.

The packaging structure 100 further includes at least one conductive wire 40. A first end of the conductive wire 40 is electrically connected to the first solder joint 11, a second end of the conductive wire 40 is electrically connected to the second solder joint 33, thereby electrically connecting the circuit board 10 and the image sensor 30. The conductive wire 40 can be a metal wire with a high conductivity such as a gold wire, a silver wire, or a copper wire. In one embodiment, the conductive wire 40 is a copper wire.

The installation bracket assembly 50 includes a first installation bracket 501 and a second installation bracket 502. The second installation bracket 502 is sleeved on an outside of the first installation bracket 501, and the first installation bracket 501 and the second installation bracket 502 are independent of each other. The second installation bracket 502 defines an installation hole 5021. An outer diameter of the first installation bracket 501 matches a size of the installation hole 5021 of the second installation bracket 502, thus the second installation bracket 502 is sleeved on the outside of the first installation bracket 501 through the installation hole 5021.

The first installation bracket 501 includes a plurality of sidewalls 5011. The sidewalls 5011 enclose a through hole 5012 thus formed. The first installation bracket 501 further includes a top surface 5013 adjacent to sides of the sidewalls 5011 away from the image sensor 30. The top surface 5013 defines a through hole for light (light through hole). A central axis of the light through hole is same as a central axis of the through hole 5012. The photosensitive surface 31 of the image sensor 30 includes a photosensitive area 34 exposed to and opposite to the light through hole, and a non-photosensitive area 35 surrounding the photosensitive area 34. The second solder joint 33 is arranged on the non-photosensitive area 35.

The first installation bracket 501 is fixed to the non-photosensitive area 35 of the image sensor 30 via the second adhesive layer 21. The first installation bracket 501 and the image sensor 30 are on same surface of the circuit board 10. In assembly, the image sensor 30 is firstly fixed on the circuit board 10, and then the first installation bracket 501 is fixed on the image sensor 30. The viscosity of the second adhesive layer 21 is less than the viscosity of the first adhesive layer 20, so that the relative positions of the first installation bracket 501 and the image sensor 30 can be adjusted. When adjusting the relative positions of the first installation bracket 501 and the image sensor 30, the image sensor 30 remains in an original position due to the first adhesive layer 20 having higher viscosity, thus any misalignment of the image sensor 30 can be reduced, and the quality of the packaging structure 100 can be improved.

The second installation bracket 502 is fixed to the circuit board 10 via the third adhesive layer 22. The second installation bracket 502 and the image sensor 30 are on same surface of the circuit board 10. In assembly, the first installation bracket 501 is firstly fixed on the image sensor 30, and then the second installation bracket 502 is sleeved on the first installation bracket 51 and fixed to the circuit board 10. The viscosity of the third adhesive layer 22 is less than the viscosity of the second adhesive layer 21, so that the position of the first installation bracket 501 can be adjusted by adjusting the position of the second installation bracket 502. Thus, any alignment difference of the image sensor 30 can be reduced, and the quality of the packaging structure 100 can be improved.

The first installation bracket 501 and the second installation bracket 502 can be made of metal or plastic. In one embodiment, the first installation bracket 501 and the second installation bracket 502 are both made of plastic.

The sidewalls 5011 of the first installation bracket 501 and the image sensor 30 enclose a first receiving space 60. The photosensitive area 34 is located in the first receiving space 60. The circuit board 10, the sidewalls 5011 of the first installation bracket 501, and the second installation bracket 502 enclose a second receiving space 61. The first solder joint 11, the second solder joint 33, and the non-photosensitive area 35 are located in the second receiving space 61. The first receiving space 60 and the second receiving space 61 are isolated from each other. External impurities tending to enter into a space can only enter the first receiving space 60 after passing through the second receiving space 61. The first receiving space 60 has a smaller volume than the second receiving space 61. External impurities can thus be prevented from entering the photosensitive area 34 in the first receiving space 60, and the imaging quality of the packaging structure 100 is improved.

The lens 210 is mounted in the through hole 5012, and is opposite to the image sensor 30.

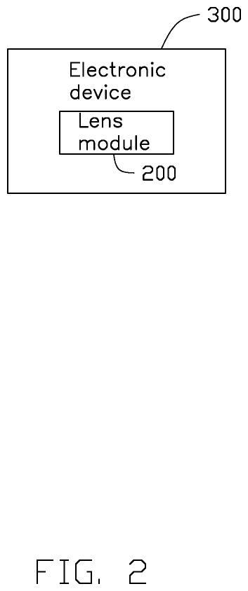

FIG. 2 illustrates an electronic device 300 including the lens module 20. The electronic device 300 can be any electronic device having imaging capturing functions, such as mobile phones, wearable devices, computer devices, vehicles, or monitoring devices.

The image sensor 30 is fixed on the circuit board 10 via the first adhesive layer 20, and the first installation bracket 501 is fixed on a surface of the image sensor 30 away from the circuit board 10 via the second adhesive layer 21. The second installation bracket 502 is sleeved on an outside of the first installation bracket 501 and is fixed to the circuit board 10 via the third adhesive layer 22. The successively lower viscosities of the first adhesive layer 20, the second adhesive layer 21, and the third adhesive layer 22 provide subsequent adjustability to the positions of the first installation bracket 501 and the second installation bracket 502 relative to the image sensor 30, without disturbing any earlier positioning. Thereby misalignments of the image sensor 30 can be reduced, and the quality of the packaging structure 100 can be improved.

Even though information and advantages of the present embodiments have been set forth in the foregoing description, together with details of the structures and functions of the present embodiments, the disclosure is illustrative only. Changes may be made in detail, especially in matters of shape, size, and arrangement of parts within the principles of the present exemplary embodiments, to the full extent indicated by the plain meaning of the terms in which the appended claims are expressed.

What is claimed is:

1. A packaging structure for image sensor comprising:
a circuit board;
an image sensor fixed on the circuit board via a first adhesive layer; and
an installation bracket assembly, the installation bracket assembly and the image sensor being on same surface of the circuit board, the installation bracket assembly comprising:
a first installation bracket fixed on a surface of the image sensor away from the circuit board via a second adhesive layer, and
a second installation bracket sleeved on an outside of the first installation bracket, the second installation being fixed to the circuit board via a third adhesive layer;
wherein viscosities of the first adhesive layer, the second adhesive layer, and the third adhesive layer decrease in an order as stated herein.

2. The packaging structure of claim 1, wherein the image sensor comprises a photosensitive surface and a non-photosensitive surface opposite to the photosensitive surface, the photosensitive surface is positioned away from the circuit board, the non-photosensitive surface is adjacent to the circuit board, the first installation bracket is fixed on the photosensitive surface, the circuit board is fixed on the non-photosensitive surface via the first adhesive layer.

3. The packaging structure of claim 2, wherein the circuit board comprises at least one first solder joint on a surface fixed to the image sensor, the image sensor comprises at least one second solder joint on the photosensitive surface, the first solder joint is electrically connected to the second solder joint.

4. The packaging structure of claim 3, wherein the packaging structure further comprises at least one conductive wire, the conductive wire connects the first solder joint and the second solder joint.

5. The packaging structure of claim 3, wherein the first installation bracket comprises a plurality of sidewalls and a top surface adjacent to sides of the sidewalls away from the image sensor, the sidewalls enclose a through hole, the top surface defines a light through hole, a central axis of the light through hole is same as a central axis of the through hole, wherein the photosensitive surface comprises a photosensitive area exposed to and opposite to the light through hole and a non-photosensitive area surrounding the photosensitive area, the second solder joint is arranged on the non-photosensitive area.

6. The packaging structure of claim 5, wherein first installation bracket is fixed on the non-photosensitive area via the second adhesive layer.

7. The packaging structure of claim 5, wherein the sidewalls of the first installation bracket and the image sensor enclose a first receiving space, the photosensitive area is located in the first receiving space, wherein the circuit board, the sidewalls of the first installation bracket, and the second installation bracket enclose a second receiving space, all of the first solder joint, the second solder joint, and the non-photosensitive area are located in the second receiving space, the first receiving space and the second receiving space are isolated from each other.

8. The packaging structure of claim 1, wherein the second installation bracket defines an installation hole, an outer diameter of the first installation bracket matches a size of the installation hole thus the second installation bracket is sleeved on the outside of the first installation bracket through the installation hole.

9. A lens module comprising:
a packaging structure comprising:
a circuit board,
an image sensor fixed on the circuit board via a first adhesive layer, and
an installation bracket assembly, the installation bracket assembly and the image sensor being on a same surface of the circuit board, the installation bracket assembly comprising:
a first installation bracket fixed on a surface of the image sensor away from the circuit board via a second adhesive layer, and
a second installation bracket sleeved on an outside of the first installation bracket, the second installation being fixed to the circuit board via a third adhesive layer; and
a lens mounted in the first installation bracket and being opposite to the image sensor;
wherein viscosities of the first adhesive layer, the second adhesive layer, and the third adhesive layer decrease in an order as stated herein.

10. The lens module of claim 9, wherein the image sensor comprises a photosensitive surface and a non-photosensitive surface opposite to the photosensitive surface, the photosensitive surface is positioned away from the circuit board, the non-photosensitive surface is adjacent to the circuit board, the first installation bracket is fixed on the photosensitive surface, the circuit board is fixed on the non-photosensitive surface via the first adhesive layer.

11. The lens module of claim 10, wherein the circuit board comprises at least one first solder joint on a surface fixed to the image sensor, the image sensor comprises at least one second solder joint on the photosensitive surface, the first solder joint is electrically connected to the second solder joint.

12. The lens module of claim 11, wherein the packaging structure further comprises at least one conductive wire, the conductive wire connects the first solder joint and the second solder joint.

13. The lens module of claim 11, wherein the first installation bracket comprises a plurality of sidewalls and a top surface adjacent to sides of the sidewalls away from the image sensor, the sidewalls enclose a through hole, the top surface defines a light through hole, a central axis of the light through hole is same as a central axis of the through hole, wherein the photosensitive surface comprises a photosensitive area exposed to and opposite to the light through hole and a non-photosensitive area surrounding the photosensitive area, the second solder joint is arranged on the non-photosensitive area.

14. The lens module of claim 13, wherein first installation bracket is fixed on the non-photosensitive area via the second adhesive layer.

15. The lens module of claim 13, wherein the sidewalls of the first installation bracket and the image sensor enclose a first receiving space, the photosensitive area is located in the first receiving space, wherein the circuit board, the sidewalls of the first installation bracket, and the second installation bracket enclose a second receiving space, all of the first solder joint, the second solder joint, and the non-photosensitive area are located in the second receiving space, the first receiving space and the second receiving space are isolated from each other.

16. The lens module of claim 9, wherein the second installation bracket defines an installation hole, an outer diameter of the first installation bracket matches a size of the installation hole thus the second installation bracket is sleeved on the outside of the first installation bracket through the installation hole.

17. An electronic device comprising:
a lens module comprising:
a packaging structure comprising:
a circuit board,
an image sensor fixed on the circuit board via a first adhesive layer, and
an installation bracket assembly, the installation bracket assembly and the image sensor being on a same surface of the circuit board, the installation bracket assembly comprising:
a first installation bracket fixed on a surface of the image sensor away from the circuit board via a second adhesive layer, and
a second installation bracket sleeved on an outside of the first installation bracket, the second installation being fixed to the circuit board via a third adhesive layer; and
a lens mounted in the first installation bracket and being opposite to the image sensor;
wherein viscosities of the first adhesive layer, the second adhesive layer, and the third adhesive layer decrease in an order as sated therein.

18. The electronic device of claim 17, wherein the image sensor comprises a photosensitive surface and a non-photosensitive surface opposite to the photosensitive surface, the photosensitive surface is positioned away from the circuit board, the non-photosensitive surface is adjacent to the circuit board, the first installation bracket is fixed on the photosensitive surface, the circuit board is fixed on the non-photosensitive surface via the first adhesive layer.

19. The electronic device of claim 18, wherein the circuit board comprises at least one first solder joint on a surface fixed to the image sensor, the image sensor comprises at least one second solder joint on the photosensitive surface, the first solder joint is electrically connected to the second solder joint.

20. The electronic device of claim 19, wherein the first installation bracket comprises a plurality of sidewalls and a top surface adjacent to sides of the sidewalls away from the image sensor, the sidewalls enclose a through hole, the top surface defines a light through hole, a central axis of the light through hole is same as a central axis of the through hole, wherein the photosensitive surface comprises a photosensitive area exposed to and opposite to the light through hole and a non-photosensitive area surrounding the photosensitive area, the second solder joint is arranged on the non-photosensitive area.
